(19) United States
(12) Patent Application Publication
(10) Pub. No.: US 2013/0089656 A1
(43) Pub. Date: Apr. 11, 2013

(54) DIRECT DISPENSE DEVICE AND METHOD

(71) Applicants: Greg McComiskey, Faribault, MN (US); Cliff Taylor, Northfield, MN (US)

(72) Inventors: Greg McComiskey, Faribault, MN (US); Cliff Taylor, Northfield, MN (US)

(73) Assignee: SAGE ELECTROCHROMICS, INC., Faribault, MN (US)

(21) Appl. No.: 13/269,167

(22) Filed: Oct. 7, 2011

(51) Int. Cl. B05C 5/00; G05D 7/06; C23C 16/52; B05D 5/00

(52) U.S. Cl. 427/8; 700/283; 427/256; 118/300

(57) ABSTRACT

A system for dispensing a viscous material includes a motion system for controlling movement of a dispensing tip within a dispensing region and delivering a viscous material at a controlled flow rate in coordination with the dispensing tip movement in order to deliver a predetermined amount of the viscous material to predetermined positions within the dispensing region. A dispensing tip in fluid communication with a pump for use with the system includes outer and inner housings and outlet holes within a space between them. A contact element within the inner housing is capable of contacting a suitable surface for dispensing viscous material. In some embodiments, a face of the outer housing located a fixed distance from an apex of the contact element maintains a uniform thickness during dispensing. A method of using the system includes controlling the movement of the dispensing tip and the flow rate of the viscous material.

### BACKGROUND OF THE INVENTION

Electrochromic glazings include electrochromic materials that are known to change their optical properties, such as coloration, in response to the application of an electrical potential, thereby making a device using such glazings more or less transparent or more or less reflective. Common uses for these glazings include office building windows, and windshields and mirrors of automobiles.

FIGS. 1A and 1B illustrate plan and cross-sectional views, respectively, of a typical prior art electrochromic device 20. The device 20 includes isolated transparent conductive layer regions 26A and 26B that have been formed on a substrate 34, such as glass. In addition, the device 20 includes a counter electrode layer 28, an ion conductive layer 32, an electrochromic layer 30 and a transparent conductive layer 24, which have been deposited in sequence over the conductive layer regions 26. It is to be understood that the relative positions of the electrochromic and counter electrode layers of the device 20 may be interchanged. Further, the device 20 includes a bus bar 40 which is in contact only with the conductive layer region 26A, and a bus bar 42 which may be formed on the conductive layer region 26B and is in contact with the conductive layer 24. The conductive layer region 26A is physically isolated from the conductive layer region 26B and the bus bar 42, and the conductive layer 24 is physically isolated from the bus bar 40. Further, the bus bars 40 and 42 are connected by wires to positive and negative terminals, respectively, of a low voltage electrical source 22 (the wires and the source 22 together constituting an “external circuit”).

Referring to FIGS. 1A and 1B, when the source 22 is operated to apply an electrical potential across the bus bars 40, 42, electrons, and thus a current, flow from the bus bar 42, across the transparent conductive layer 24 and into the electrochromic layer 30.

Bus bars are traditionally made by firing a glass frit material on a substrate. The glass frit material (hereinafter “frit”) is generally made of flakes of conductive materials such as silver, palladium, copper, gold, and lead, which when combined with oxygen, facilitates firing of the bus bar. Frits also contain other materials such as glass beads that fuse the frit to the substrate when the bus bar is fired, solvents that keep the frit wet during application, and organic binders that hold the bus bar together until firing of the bus bar. Other classes of materials that do not use glass beads may also be used. These materials typically contain less silver and are usually approximately about one-tenth as conductive as the frit materials. These materials rely on organic materials, such as epoxies, to bond them to the surface and are fired at much lower temperatures.

The frit is generally applied in a linear fashion to the substrate by screen printing or by extrusion through a nozzle attached to a syringe or attached to an auger pump. Screen printing is the most common method and requires a dedicated screen for a desired bus bar pattern or substrate size. Syringes, which are typically designed for hand dispensing need to be refilled or replaced often and usually do not allow accurate control of the thickness of the ink flow. Auger pumps utilize a motor to supply the force necessary to expel the material and thus allow more accurate control of the thickness and faster application of the material. In these types of pumps, thickness is set by holding the dispense tip a fixed distance off the substrate surface. Thus, systems utilizing these pumps require mapping of the substrate surface prior to printing to assure uniform thickness and width of the bus bar.

The substrate may be comprised of glass, a polymeric material such as resins or acrylates, an electrochromic device, or a laminate. It is believed that such deposition systems exhibit at least one of (a) poor thickness control, especially at the beginning and ends of the produced frit lines or when printing curved lines; (b) have limited dispense speed capabilities; (c) require frequent stops for refilling of frit material; (d) have limited dispense tip life; or (e) require frequent operator intervention for adjustment and/or corrective action. Therefore, there exists a need for an improved frit dispensing system.

### BRIEF SUMMARY OF THE INVENTION

In one aspect of the present invention may be a system and method for directly dispensing a uniform bead of a viscous material.

In another aspect of the present invention may be a system and method for directly dispensing a uniform bead of a viscous material in predetermined lines and/or patterns onto a substrate.

In another aspect of the present invention, may be a system or device used to deposit a uniform bead of a viscous material onto a substrate, where the system includes a fluid source capable of supplying and/or storing a viscous material at a predetermined pressure, a translational device capable of moving in a predetermined manner, and a dispensing outlet attached to the translational device for delivering the viscous material. In some embodiments, such systems for applying a viscous material may include (i) a durable self-gapping dispensing tip with tightly-controlled dimensional tolerances, (ii) a fast responding Z-axis actuator that accurately controls forces applied by the dispensing tip to the substrate, and (iii) a directly controllable, variable flow rate, variably accelerating and/or decelerating, positive displacement pump with forward and reverse pumping capability.

In another aspect of the invention may be a dispensing tip capable of fluid communication with a pump that may be used to dispense a viscous material. The dispensing tip may include an outer housing and an inner housing that is engaged with and located within the outer housing. The tip may also include a contact element that is engaged with and located within the inner housing. The contact element may extend outside of the outer and inner housings. The contact element may be made of stainless steel, sapphire, polycrystalline diamond, or other hard materials. The contact element may have a spherical, cylindrical, or other shape that may have an apex. The outer housing, the inner housing, and the contact element may define a space, and the dispensing tip may further include at least one outlet hole that is located within the space. The apex of the contact element may be at a distance from a face of the outer housing that remains substantially constant.

In another aspect of the present invention is a dispensing tip capable of fluid communication with a pump for use in dispensing a viscous material comprising an outer housing; an inner housing engaged with and located within the outer housing; a contact element engaged with and located within the inner housing, the contact element extending outside the outer and inner housings; and at least one outlet hole located within a space defined by the outer housing, the inner housing, and the contact element. In some embodiments, the contact element includes an apex, the apex being substantially a point surface capable of contacting a suitable surface for receiving the viscous material. In some embodiments, at least one outlet hole includes an inner portion defined by the outer housing and the inner housing and an outer portion defined by the outer housing and the contact element. In some embodiments, the dispensing tip has at least two outlet holes spaced apart equally along a circumference within the space. In some embodiments, the contact element retains substantially the same shape at an applied force of less than 3 lbs. In some embodiments, the contact element is made of a material selected from the group consisting essentially of stainless steel, sapphire, and polycrystalline diamond. In some embodiments, the space has a volume between about 0.2 cubic centimeters and about 0.25 cubic centimeters. In some embodiments, the contact element has a cylindrical central portion. In some embodiments, the contact element is spherical. In some embodiments, the outer housing is threadedly engaged with the inner housing. In some embodiments, the outer housing has a face, wherein a distance between the face and the apex remains substantially constant. In some embodiments, the engagement of the inner housing and the contact element is an interference fit.

In another aspect of the invention may be a computer-controlled system for dispensing a viscous material within a region. The system may include a motion system that may be capable of receiving at least one signal and of moving to predetermined positions in response to the at least one signal received by the motion system. The system may further include a variable pressure supply device that may be capable of receiving at least one signal and of delivering a fluid in response to the at least one signal received by the motion system. The motion system may also include a dispensing tip. The dispensing tip may have an end that defines X-, Y-, and Z-positions within the region. The dispensing tip may be coupled to the motion system such that it moves with the motion system to predetermined X-, Y-, and Z-positions within the region. The dispensing tip may also be in fluid communication with the variable pressure supply device.

A computer-controlled system for dispensing a viscous material within a region having X-, Y-, and Z-positions includes a motion system capable of (i) receiving at least one signal and (ii) moving to predetermined positions in response to the at least one signal received; a variable pressure supply device capable of (i) receiving at least one signal and (ii) delivering a fluid in response to the at least one signal received; and a dispensing tip having an end that defines its X-, Y-, and Z-positions, the dispensing tip being (i) coupled to the motion system such that it moves with the motion system to predetermined X-, Y-, and Z-positions, (ii) being in fluid communication with the variable pressure supply device, and (iii) including an outer housing having a face, in which a distance between the face and the apex remains substantially constant.

In another aspect of the present invention is a computer-controlled system for dispensing a viscous material within a region having X-, Y-, and Z-positions comprising a motion system capable of (i) receiving at least one signal and (ii) moving to predetermined positions in response to the at least one signal received; a variable pressure supply device capable of (i) receiving at least one signal and (ii) delivering a fluid in response to the at least one signal received; and a dispensing tip having an end that defines its X-, Y-, and Z-positions, the dispensing tip being (i) coupled to the motion system such that it moves with the motion system to predetermined X-, Y-, and Z-positions, and (ii) in fluid communication with the variable pressure supply device. In some embodiments, the variable pressure supply device is a pump capable of (i) receiving an input signal from the motion system and (ii) adjusting the flow rate to a rate proportional to the input signal.

In some embodiments, the computer-controlled system further comprises a user interface capable of receiving and transmitting data; and a controller capable of (i) receiving any of the data, (ii) converting any of the data into the signals, and (iii) transmitting any of the signals. In some embodiments, the data includes predetermined pump flow rates, predetermined displacement parameters, predetermined speed parameters, and predetermined acceleration parameters, and the signals include flow rate signals, displacement signals, speed signals, and acceleration signals. In some embodiments the computer-controlled system for dispensing a viscous material is further adapted for dispensing the viscous material from the dispensing tip onto a substrate, wherein the end of the dispensing tip is a center stylus capable of locating and maintaining contact with the substrate at predetermined positions. In some embodiments, the dispensing tip further comprises at least one outlet hole capable of dispensing viscous material.

In another aspect of the invention may be a method of depositing or applying a bus bar or soldering tab onto a substrate. In some embodiments, the substrate is an EC device. In general, this method may include the steps of (a) moving at least a dispensing tip to a predetermined starting position; (b) dispensing a viscous material from the dispensing tip at a predetermined flow rate along a predetermined path beginning at the starting position; and (c) halting the movement of the dispensing tip and the flow of viscous material from the dispensing tip when a predetermined ending position is reached. In some embodiments, these steps may be repeated at various times throughout application of the viscous material onto the substrate to deposit segmented bus bars or bus bars having dots.

In another aspect of the invention may be a method for uniformly dispensing a viscous material within a dispensing region. The method may include a step of moving a dispensing tip in a controlled direction at a controlled speed and acceleration within the dispensing region. The method may include a step of delivering the viscous material at a controlled flow rate in coordination with the step of moving the dispensing tip in order to deliver a predetermined amount of the viscous material to predetermined positions within the dispensing region.

A method for uniformly dispensing a viscous material within a dispensing region includes the steps of moving a dispensing tip in a controlled direction at a controlled speed and acceleration within the dispensing region; and delivering the viscous material at a controlled flow rate in coordination with the step of moving the dispensing tip to deliver a predetermined amount of the viscous material to predetermined positions within the dispensing region, in which the dispensing tip includes an outer housing having a face, in which a distance between the face and the dispensing region remains substantially fixed to form a uniform thickness of viscous material.

In another aspect of the present invention is a method for uniformly dispensing a viscous material within a dispensing region comprising the steps of moving a dispensing tip in a controlled direction at a controlled speed and acceleration within the dispensing region; and delivering the viscous material at a controlled flow rate in coordination with the step of moving the dispensing tip to deliver a predetermined amount of the viscous material to predetermined positions within the dispensing region. In some embodiments, the method further comprises the steps of receiving a stop command at a predetermined tab stop position; decelerating the dispensing tip to a lower controlled speed at the predetermined stop position; and reducing the flow rate to a lower controlled flow rate for delivering the viscous material after reaching the predetermined stop position. In some embodiments, the dispensing tip comprises an outer housing having a face, wherein a distance between the face and the dispensing region remains substantially fixed to form a uniform thickness of viscous material.

In some embodiments, the dispensing tip is in fluid communication with a variable pressure supply device, the variable pressure supply device being capable of producing variable flow rates, and wherein the dispensing tip is coupled to a motion system, the motion system being movable in three dimensions, and further comprising the steps of receiving a signal at an electrical interface of the variable pressure supply device from the motion system; and adjusting the flow rate of the variable pressure supply device to supply viscous material to the dispensing tip such that the dispensing tip dispenses a predetermined uniform amount of the viscous material. In some embodiments, the dispensing region is substantially linear. In some embodiments, the viscous material is glass frit. In some embodiments, the dispensing region is a projection of a soldering tab. In some embodiments, the dispensing region is a projection of a bus bar. In some embodiments, the dispensing region includes at least a portion of a substrate.

In some embodiments, the dispensing region includes a soldering tab portion in which the viscous material will be dispensed, the method further comprising the steps of receiving a first delay value prior to dispensing the viscous material in the soldering tab portion, wherein a delay value corresponds to a time between movement of the dispensing tip and activation of a variable pressure supply device, the variable pressure supply device being in fluid communication with the dispensing tip.

In some embodiments, the dispensing region further includes a bus bar portion in which the viscous material will be dispensed, the method further comprising the steps of receiving a second delay value, prior to dispensing the viscous material in the bus bar portion; reactivating the variable pressure supply device; and further delivering the viscous material at a controlled flow rate in coordination with the step of moving the dispensing tip to deliver a predetermined amount of the viscous material at predetermined coordinates onto the substrate within the dispensing region; further moving the dispensing tip in a controlled direction at a controlled speed and acceleration along the substrate within the entire dispensing region; decelerating the dispensing tip to a lower controlled speed immediately after the receiving of a stop command at a predetermined tab stop position; and reducing the flow rate to a lower controlled flow rate for delivering the fluid after reaching a predetermined stop position, stopping the delivering of the fluid after the reducing of the flow rate; stopping the movement of dispensing tip at a predetermined location; and returning the dispensing tip to the home position.

It is believed that at least one of these aspects of the present invention allows for application of a uniform bead of viscous material over a variety of substrates, including those with irregular surfaces, concave surfaces, or convex surfaces. It is also believed that the present invention allows for application of a uniform bead of viscous material having any pattern, including straight lines, curved lines, segmented lines, or pinpoint dots.

### BRIEF DESCRIPTION OF THE DRAWINGS

These and other features, aspects, and advantages of the present invention will become better understood with regard to the following description, appended claims, and accompanying drawings in which:

FIG. 1A is a top plan view of a prior art electrochromic device.

FIG. 1B is a view of the electrochromic device of FIG. 1A at cross-sectional line 1B-1B.

FIG. 2 is a schematic diagram of a system for dispensing viscous material in accordance with the present invention.

FIG. 3 is a dispensing module in accordance with the present invention.

FIG. 4 is a side cross-sectional view of a dispensing tip having a polycrystalline diamond tip in accordance with the present invention.

FIG. 5 is a detailed view of the dispensing tip shown in FIG. 4.

FIG. 6 is a detailed view of a contact element of a dispensing tip.

FIG. 7 is a bottom view of the dispensing tip shown in FIG. 4.

FIG. 8 is a side cross-sectional view of a pump and substrate in accordance with the present invention.

FIG. 9 is a plan view of the pump and substrate shown in FIG. 2.

FIG. 10 is an expanded view of frit material applied to a substrate using the system shown in FIG. 2.

FIG. 11 is a diagram showing the effect of the incline of a dispensing tip on the size of the gap created under the dispensing tip.

FIG. 12 is a process flow diagram of a method of use of the system shown in FIG. 2.

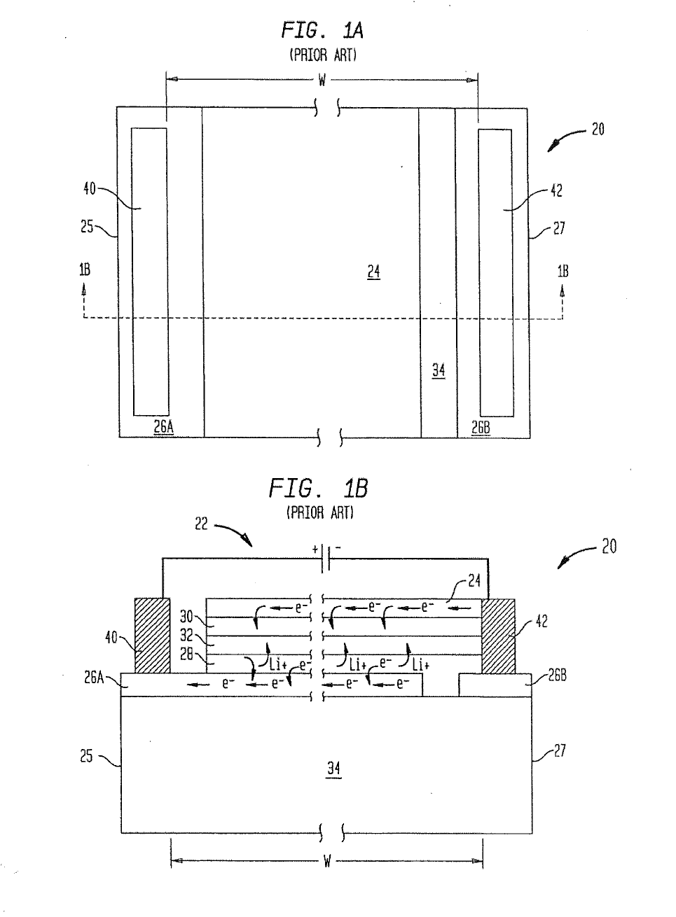

### DETAILED DESCRIPTION OF THE INVENTION

In the Brief Summary of the Invention above and in the Detailed Description of the Invention, and the claims below, and in the accompanying drawings, reference is made to particular features (including method steps) of the invention. It is to be understood that the disclosure of the invention in this specification includes all possible combinations of such particular features. For example, where a particular feature is disclosed in the context of a particular aspect or embodiment of the invention, or a particular claim, that feature can also be used, to the extent possible, in combination with and/or in the context of other particular aspects and embodiments of the invention, and in the invention generally.

The term “comprises” and grammatical equivalents thereof are used herein to mean that other components, ingredients, steps, etc. are optionally present. For example, an article “comprising” (or “which comprises”) components A, B, and C can have (i.e., contain only) components A, B, and C, or can have not only components A, B, and C but also one or more other components.

Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility).

The term “at least” followed by a number is used herein to denote the start of a range beginning with that number (which may be a range having an upper limit or no upper limit, depending on the variable being defined). For example, “at least 1” means 1 or more than 1. When, in this specification, a range is given as “(a first number) to (a second number)” or “(a first number)-(a second number),” this means a range whose lower limit is the first number and whose upper limit is the second number. For example, 25 to 100 mm means a range whose lower limit is 25 mm, and whose upper limit is 100 mm.

### Direct Dispense System

In one aspect of the present invention is a system for dispensing a viscous material.

As used herein, the term “viscous material” refers to a formulation that is in the form of a liquid or gel or in a semi-solid state. In some embodiments, the viscous material may comprise a solvent or a carrier in which particles, including nanoparticles, are suspended, dispersed, or distributed therein. In some embodiments, viscous materials in accordance with the present invention have a viscosity between about 20,000 and about 30,000 centipoise.

In other embodiments, viscous materials in accordance with the present invention include conductive particles in a matrix of organic or inorganic material and, in some embodiments, may further include organic binders and glass frits. Conductive particles in the viscous materials may include silver flakes, nano-particulate silver, gold, palladium, silver and carbon mixtures, silver-coated carbon particles, copper particles, and silver-coated copper particles.

In yet other embodiments, viscous materials in accordance with the present invention include conductive polymers comprised of a material selected from the group consisting of an adhesive, resin, or polymer impregnated with a suitable conductive metal or an intrinsically conductive polymer. In one embodiment, the viscous material is Five Star Technologies conductive paste, Electrosperse™ D-126J (product #1077).

As used herein, the term “substrate” refers to a surface onto which a viscous material may be applied. In some embodiments, the substrate is selected from a polymeric material, metal or glass. In other embodiments, the substrate is a surface pretreated with a continuous or discontinuous inorganic or organic film. In yet other embodiments, the substrate is an electrochromic device. In further embodiments, the substrate is a soldering tab.

The substrate may have any thickness. In some embodiment, the substrate has a thickness of between about 1 mm and about 6 mm. The substrate may be of any shape or size. In some embodiments, the substrate is substantially flat. In other embodiments, the substrate has a convex or concave shape.

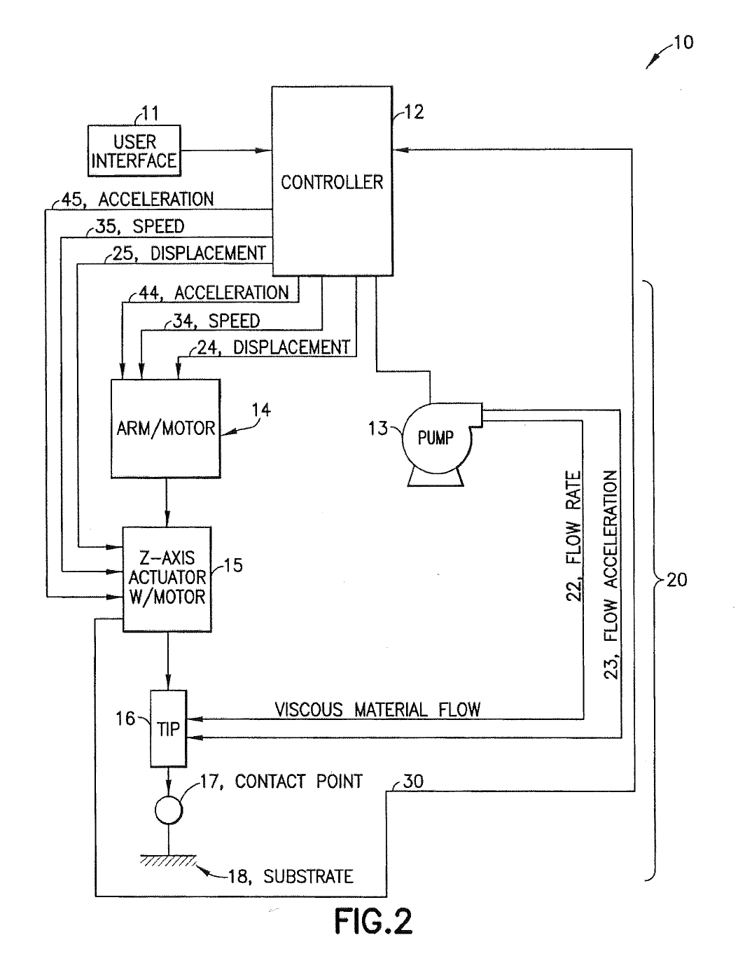

In one embodiment, as shown in FIG. 2, the dispensing system 10 includes a user interface 11, a controller 12, a pump 13, an arm 14, including a motor 21, an actuator 15, a dispensing tip 16 having a contact element 17, and a substrate 18. In some embodiments, the arm, actuator, and dispensing tip collectively comprise a motion system, such that the dispensing tip and contact element may be positioned and moved by the collective motions of the arm and actuator. In other embodiments as shown in FIG. 2, a motion system 20 comprises the pump 13, the arm 14, the actuator 15, and the dispensing tip 16.

The user interface 11 may be any device known in the art that allows users to input relevant parameters into the system and output instructions to the controller 12. It is to be understood that the user interface 11 and controller 12 may comprise separate user interfaces and controllers for separate elements of the system. For instance, a separate user interface for inputting flow rate values and/or a controller for receiving signals and transmitting to the pump 13 flow rate values corresponding to the signals received. Relevant parameters which may be entered into the user interface 11 include, but are not limited to, (a) start and end coordinate positions of the dispense tip 16 or contact element 17, (b) start and end coordinate positions of the bus bars and soldering tabs; (c) speed and acceleration/deceleration of motion values for each component of the motion system, (d) direction of motion values for each component of the motion system, (e) pump 13 or arm 14 delay values, (f) offset values based on a location of the bus bar or soldering tabs, (g) reverse motion values for the pump as part of a “suckback”, or momentary flow reversal, operation such as a delay value corresponding to the time between stopping the pump and reversing the motion of its active mechanism and a predetermined suckback quantity, (h) an equalization speed of the motion system, (i) pump overload protection value to stop the pump if the tip becomes clogged, and (j) a dosing quantity corresponding to the amount to dispense during a particular interval or at a particular location.

In some embodiments, the user interface is a software program, such as LABVIEW, loaded onto a personal computer. In other embodiments, the user interface is an independent programmable logic controller (PLC) or any other suitable device known to those of skill in the art.

The controller 12 receives parameters from the user interface 11 and, in general, directs the action of the other system components. The controller 12 sends signals or instructions, based on parameters received from the user interface 11, to the arm 14 to move in the X-Y coordinate directions (i.e., directions parallel to the substrate 18 surface). The controller 12 also sends signals or instructions, based on parameters received from the user interface, to the actuator 15 to move in the Z-coordinate direction (i.e., direction perpendicular to the substrate 18 surface). In general, the controller 12 sends independent signals or instructions to the arm 14 and/or actuator 15 directing motion at a predetermined speed (34, 35) and predetermined acceleration (44, 45) and to a predetermined displacement (24, 25). In some embodiments, the arm 14 is fixed to the actuator 15 such that the translational speed and displacement of the arm 14 results in a corresponding speed and equivalent displacement of the actuator 15 in the X-Y coordinate directions.

The controller 12 also sends signals or instructions to a pump 13, based on parameters received from the user interface 11, to control the rate and acceleration of flow of a viscous material (22, 23) from the pump 13. It is to be understood that the dispensing system 10 may have one or more controllers that may perform some or all of the functions or even additional functions described for the controller 12 herein. In some embodiments, the controller for the pump 13 may be part of the motion system 20. In such an arrangement, the pump 13 may be capable of receiving an input signal (in the form of a voltage or current) from the motion system 20 and accordingly adjusting its speed and the corresponding flow rate based on a preprogrammed formula.

For instance, the motion system 20 may provide an output voltage that is proportional to the motion system speed. The output voltage may be between from about 0 to about 10 volts. In this manner, the pump speed can change dynamically as the motion system 20, and in particular the dispensing tip 16, moves through a curve in a plane parallel to the substrate 18 and changes its speed in the X- and Y-directions. It is believed that such a feature will enable faster dispensing of viscous material by having the system regulate the viscous material dispensing rate without user intervention.

The pump 13 itself may be fixed to the arm 14 or the actuator 15 or may be fixed at a remote location. As such, movement of the arm 14 and/or the actuator 15 may also result in a concomitant movement of the pump 13. In this manner, it is believed that the pump can accurately deliver a predetermined amount of the viscous material. In some embodiments, the pump may deliver the viscous material without generating particles such as agglomerates, cold welded flakes, or other particles that may not be desired.

A dispensing tip 16 is in fluidic communication with the pump 13 and may be fixed to the outlet of the pump 13 or may be connected through fluid lines or hoses to the pump 13. In some embodiments, the dispensing tip 16 is fixed directly to the actuator 15. In other embodiments, the dispensing tip 16 is fixed to the pump 13, where the pump is attached to the actuator. In either embodiment, a displacement and speed of the actuator 15 in any direction results in a corresponding and substantially equivalent displacement of the dispensing tip 16.

Direct connections between the arm 14, the actuator 15, the pump 13, and the dispensing tip 16 may be threaded connections, welded connections, or any other suitable connections, or these elements may be connected through a solid, monolithic structure.

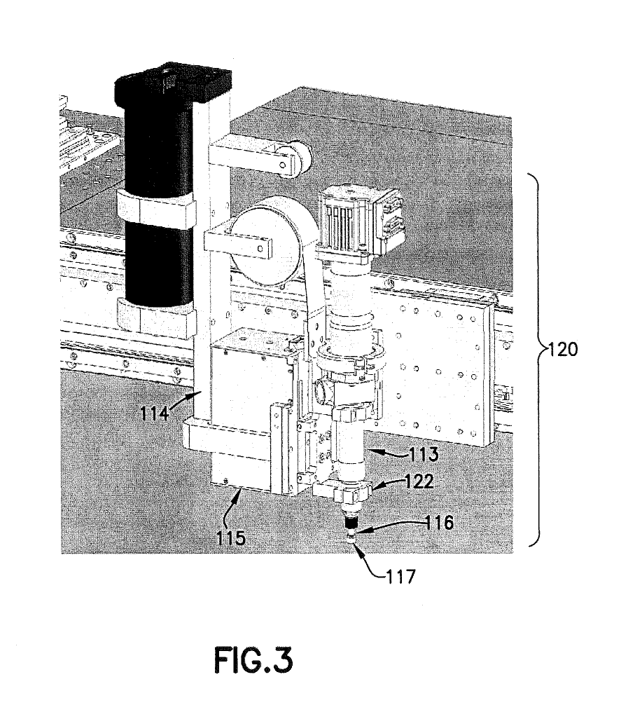

In another embodiment, shown in FIG. 3, is a motion system 120 having an arm 114, a pump 113, an actuator 115, and a dispensing tip 116. The pump 113 and a plate 122 are fixed to the actuator 115. The dispensing tip 116 is anchored to the plate 122 and is directly connected to the outlet of the pump 113. A contact element 117 is mounted on the end of the dispensing tip 116. In the arrangement provided, the arm moves in the directions parallel (X, Y coordinate directions) to a substrate while the actuator 115 moves in a direction perpendicular (Z-coordinate direction) to the substrate. Collectively, the motion system 120 provides motion in the X, Y, and Z directions at a predetermined rate over a predetermined pathway such that once the pump is activated, viscous material may be dispensed in a predetermined fashion.

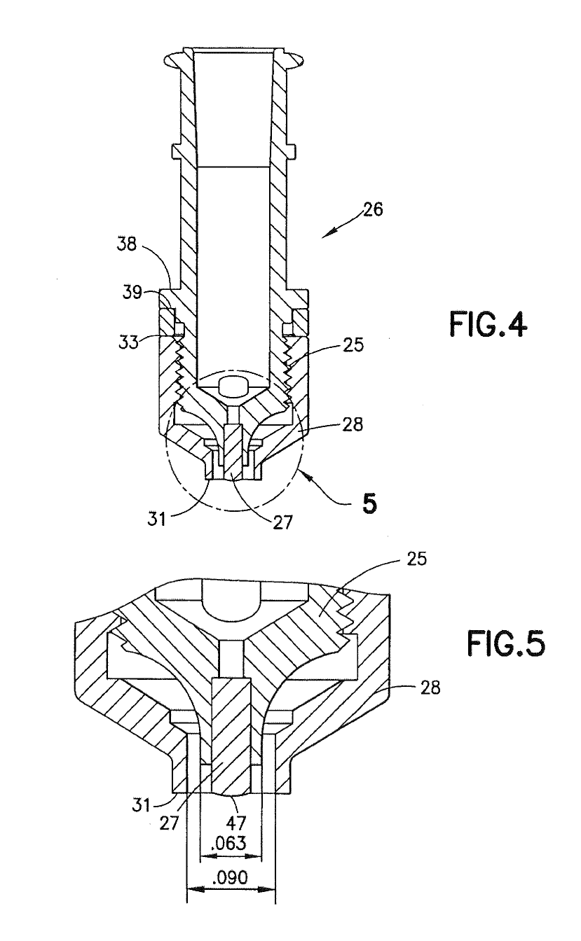

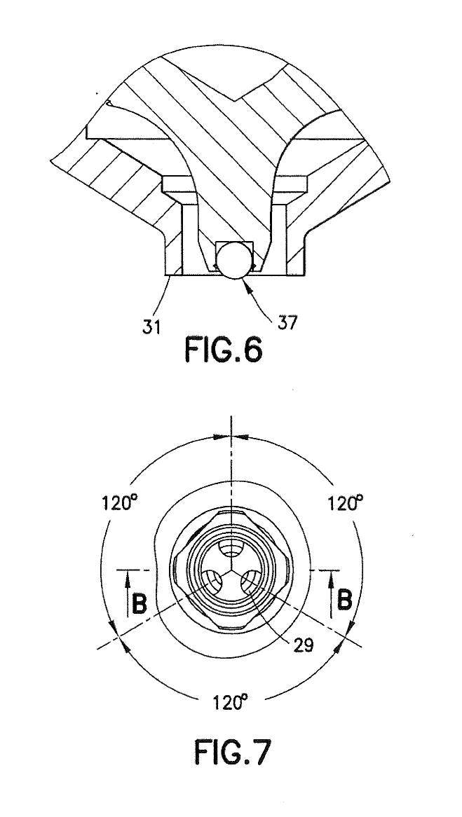

FIGS. 4 and 5 show renderings of a dispensing tip 26 having a contact element 27 mounted in the center of an inner tube 25 which may be located within and/or fixed to an outer tube 28. The contact element 27 may be cylindrical having two opposing faces and a circular cross-section as shown in the detailed view of FIG. 4. Alternatively, the contact element may be spherical as shown by contact element 37 in FIG. 6. Each contact element 27 or 37 may have an apex 47 oriented relative to the Z-axis and positioned at the point nearest the substrate along the Z-axis such that the apex 47 is capable of contacting a substrate. The outer tube 28 may have a face 31. The face 31 may be flat such that it is a fixed distance in a direction parallel to the Z-axis from the apex 47. When the apex 47 contacts a substrate, the outer tube 28 may function like a “doctor-blade” to smooth viscous material as the dispensing tip 16 moves and dispenses such material. By maintaining a fixed distance between the outer tube 28 and the apex 47, the thickness of viscous material remains substantially the same as it is dispensed.

The contact element 27 shown in FIGS. 4 and 5 is intended to withstand a force within a range of about 1 to about 3 lbs., when contacting the substrate. In some embodiments, the contact elements may be made of stainless steel, sapphire, or polycrystalline diamond (PCD). It is believed, without wishing to be bound by any particular theory, that a contact element made from PCD will exhibit less wear and have a longer useful service life as compared to other materials, such as sapphire or stainless steel, which have a much shorter and highly variable service life. Should the contact element wear, material may be added to the outer tube 28 to maintain a fixed distance between the face 31 and the apex 47. As shown in FIG. 5, in one arrangement, a shim (not shown) or shims may be inserted between a flange 38 extending from the inner tube 25 and an end 39 of the outer tube 28 that is opposite the face 31 to maintain this fixed distance. In another arrangement, a shim or shims may be inserted between the inner tube 25 and the contact element 37 or 47. In one embodiment, either of the outer tube 28 or the contact element 37 or 47 may be dynamically adjustable such that they move along the longitudinal axis of the dispensing tip 16.

In one embodiment, a plurality of outlet holes is positioned within a space between an inner tube and an outer tube. Those skilled in the art will be able to select the appropriate number and arrangement of outlet holes to provide for the desired dispensing of viscous material. Factors for making this selection may include the level of uniformity of the distribution of material flow required through the interior of the tip and/or the level of acceptable backpressure which can be reduced by exposing sufficient open area. For instance, a uniform distribution may be created by spacing three or four round holes such that they are equidistant from one another and within the space between the inner tube and the outer tube. In another embodiment, the viscous material is dispensed through two equally sized elongated holes equidistant from one another at both ends of the elongated holes and within the space between the inner and outer tubes to create a uniform distribution of material.

In yet another embodiment, as illustrated in FIG. 7, three outlet holes 29 having substantially the same shape and size are spaced apart equally about 120 degrees within a space between an inner tube 25 and an outer tube 28. In this particular embodiment, each of the outlet holes 29 is elevated above the apex 47. In such an arrangement, a viscous material may exit the dispensing tip 26 through each of the holes 29. As stated above, the flow rate from the dispensing tip is predetermined and based on the parameters provided from the user interface. It is believed, without being bound by any particular theory, that this configuration allows for a substantially even distribution of viscous material as it flows through and out of the dispensing tip 26. Furthermore, it is believed that such a design would allow bus bars to be printed having any conformation, including linear bus bars and curved bus bars, without the need for a rotating dispense head.

In the arrangement shown in FIG. 4, viscous material is held within the dispensing tip 26 in the space between the inner tube 25 and the outer tube 28. In one embodiment, the dispensing tip 26 may contain a volume of viscous material ranging from about 0.2 cm³ to about 0.25 cm³ in addition to material stored within a pump supplying material to the dispensing tip 26 and between an exit chamber of the pump and the dispensing tip 26. It is believed that by maintaining a predetermined volume of viscous material within the dispensing tip, undesirable intermittent flow from the dispensing tip 26 could be prevented. It is also believed, without wishing to be bound by any particular theory, that such a volume will require significantly less time before changes in pump speed will have corresponding changes in the flow rate of the material exiting the dispensing tip. It is believed that Newtonian (i.e., fluids having a shear stress linearly proportion to the rate of shear strain), non-compressible, and uniformly viscous fluids, such as water, will change their flow rates contemporaneously with corresponding changes in pump speed. Non-Newtonian material (i.e., fluids having a shear stress nonlinearly proportional to the rate of shear strain), such as the frit material, may be slightly compressible. It is believed that these non-Newtonian materials may then expand and contract with changes in the pressure and speed of the pump. Furthermore, any air in the non-Newtonian material will likewise expand and contract. It is thus preferred that minimizing the volume between the exit of the pumping chamber and the exit of the dispensing tip be kept to a minimum when using non-Newtonian materials.

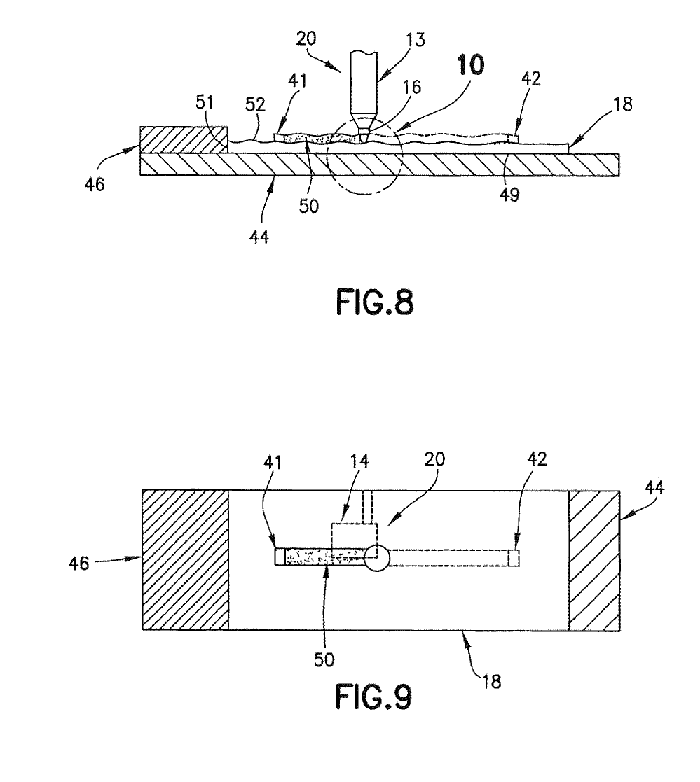

Referring now to FIGS. 8 and 9, the substrate 18 rests upon a table surface 44. In a preferred arrangement, the table surface 44 is substantially flat and establishes a plane parallel to the X-Y coordinates in which the motion system may move. In this manner, the dispensing tip 16 may be allowed to contact the table surface 44 such that the position of the dispensing tip 16 along the Z-axis (i.e., the vertical position of the tip) may be acquired. In this way, the table surface acts as a datum reference, as discussed herein.

The substrate 18 may also have a side surface 51 that is capable of contacting a reference fixture 46. In a preferred arrangement, the reference fixture 46 is substantially flat such that it is parallel to the Z-axis. In such a configuration, the reference fixture 46 may act as a datum reference to locate the position of the dispensing tip 16 in the X-Y directions, i.e., the horizontal position of the tip 16.

As further illustrated in FIGS. 8 and 9, tabs may be placed on the substrate 18. Although the arrangement shown has a first tab 41 and a second tab 42, additional tabs may be placed on the substrate 18. The tabs 41 and 42 may be made from any suitable conductive material including, but not limited to, indium, copper, silver, gold, or tin. Preferably, the bus bar comprises the same material as the tabs. The tabs may serve as positive and negative terminals and, when bridged by a bus bar, serve as a conduit for electrical current.

As shown in the Figures, a viscous material 50, such as frit, may be applied between the tabs 41 and 42. In some embodiments, the bus bar is in electrical communication with at least one surface of the tabs and, in other embodiments, at least partially covers at least one of the tabs.

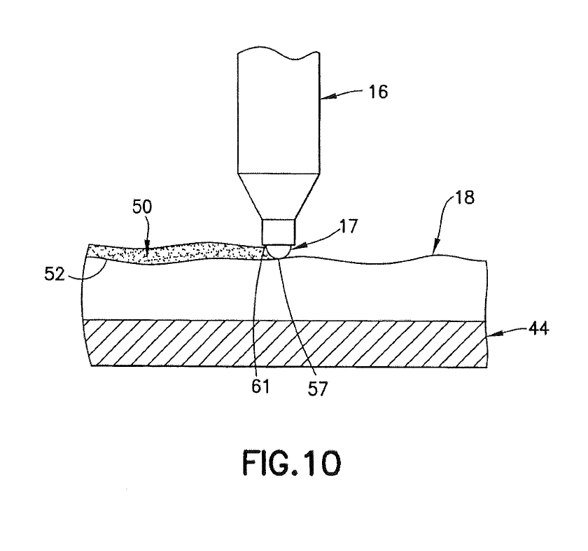

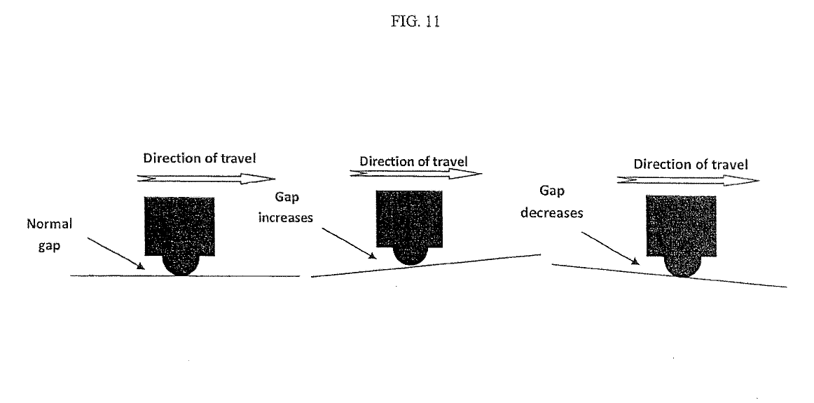

FIG. 10 shows an expanded view of a section of FIG. 8, and in particular shows the viscous material 50 being applied to a top surface 52 of the substrate 18 through a dispensing tip 16. In this preferred arrangement, the motion system 20 has a dispensing tip 16 that includes the contact element 17. In the arrangement shown, the contact element 17 is centered between outlet holes (not shown, but previously described), similar to the spacing of the outlet holes 29 of the dispensing tip 26 described herein. Furthermore, the contact element 17 has an apex 57 capable of contacting the substrate 18 in a manner similar to the apex 47. The outer tube 28 may have a face 61. Due to the fixed distance between the face 61 and the apex 57, the thickness of viscous material remains substantially the same and the thickness of the viscous material 50 remains uniform as it is dispensed from the dispensing tip 16, as shown in FIG. 10.

Although the top surface 52 may appear to be substantially flat as illustrated in FIG. 8, the expanded view of FIG. 10 shows that the top surface 52 may have surface contours, e.g., “picture frame”, “roller wave”, or similar defects, due, it is believed, to warping during tempering of the substrate or other limitations in the manufacturing of the substrate 18. It is believed that placement of the contact element in the center of the dispensing tip and placement of the apex such that it contacts the substrate may compensate for these characteristic contours of the substrate. In general, the dispensing tip should remain perpendicular to the surface to produce a bus bar having a uniform thickness (as it is believed that the thickness of the dispensed viscous material is dictated by a gap formed between the substrate and the face of the outer tube when the apex contacts the substrate). FIG. 11 shows a diagram of three orientations of the substrate with respect to the dispensing tip. As shown, the gap increases or decreases as the substrate contour changes (e.g., goes uphill or downhill). Referring again to FIG. 10, the motion system 20 may be configured such that the viscous material 50 is dispensed from the dispensing tip 16 only upon contact of the apex 47 with the substrate 18. Furthermore, the equally spaced outlet holes 29 distribute a substantially even amount of frit around the contact element 17. In this manner, it is believed that the applied viscous material, once cured, will have substantially improved mechanical straightness and a uniform thickness.

It is also believed that the dispensing system described herein would allow bus bars to be printed on uneven, convex, or concave surfaces. However, on noticeably uneven, convex, or concave surfaces, the tip would not remain substantially perpendicular to the surface. Thus, additional hardware, such as a pin or swivel for the dispensing tip to rotate around, would be needed to adjust the angle of the tip toward the surface to maintain perpendicularity, as well as additional software to compensate for the contours, such as by changing the pump speed in response to changes in the vertical direction or Z-coordinates of the dispensing tip.

### Direct Dispense Method

In another aspect of the present invention is a process of dispensing a viscous material onto a substrate. In general, this method comprises the steps of (a) moving at least a dispensing tip to a predetermined starting position; (b) dispensing a viscous material from the dispensing tip at a predetermined flow rate along as the dispensing tip is moved along a predetermined path beginning at the starting position; and (c) halting the movement of the dispensing tip and/or the flow of viscous material from the dispensing tip when a predetermined ending position is reached.

In some embodiments, the method comprises the steps of (a) moving a dispensing tip to a predetermined starting position; (b) lowering the dispensing tip onto a substrate; (c) activating a pump to begin flow of the viscous material at a predetermined rate; (d) activating movement of the dispensing tip along a predetermined path beginning at the starting position; (e) deactivating the pump such that flow of viscous material decelerates to a predetermined rate; and (f) halting movement of a dispensing tip when a predetermined ending position is reached.

In some embodiments, the dispensing tip is part of a motion system as described herein. In some embodiments, the pump, which may be part of the motion system, may be activated before or after activation of the motion system and according to a preset delay value.

The delay value may be positive or negative. A positive delay value directs the pump to activate first while a negative delay value directs the motion system to activate first. The delay value may correspond directly to the viscosity of the fluid being dispensed since, it is believed, materials having different viscosities will have different flow rates and ultimately affect the rate at which material will flow from the dispense tip. For example, for a highly viscous material, the pump may start flowing material such that the material will be dispensed from a tip at about the same time the motion system reaches a coordinate position where material is initially dispensed. The opposite, it is believed, would be true for a material having a low viscosity. In those situations, it may be desirable for the motion system to activate prior to the pump being activated since those low viscosity materials may flow quickly through the dispense tip. Such a feature enables a uniform quantity of viscous material to be applied at all positions in which the dispensing tip travels. The absolute value, however, of the delay value determines the duration of the delay in milliseconds.

In another aspect of the invention is a process of preparing a bus bar on a substrate. The process is generally conducted in two stages. Referring now to FIG. 11, in a first stage, a series of steps are employed to dispense a viscous material to form a soldering tab. In a second stage, a series of steps are employed to print a main bus bar. In some embodiments, a bus bar is printed which bridges two soldering tabs.

In general, the two stages of preparing a bus bar on a substrate comprise the same general steps. While the description which follows details a specific embodiment of dispensing a viscous material onto a soldering tab, the same general principles are applicable to dispensing or printing the main bus bar. Those of skill in the art will also recognize that the same general principles are applicable to dispensing any viscous material onto any substrate in accordance with the objectives of the present invention.

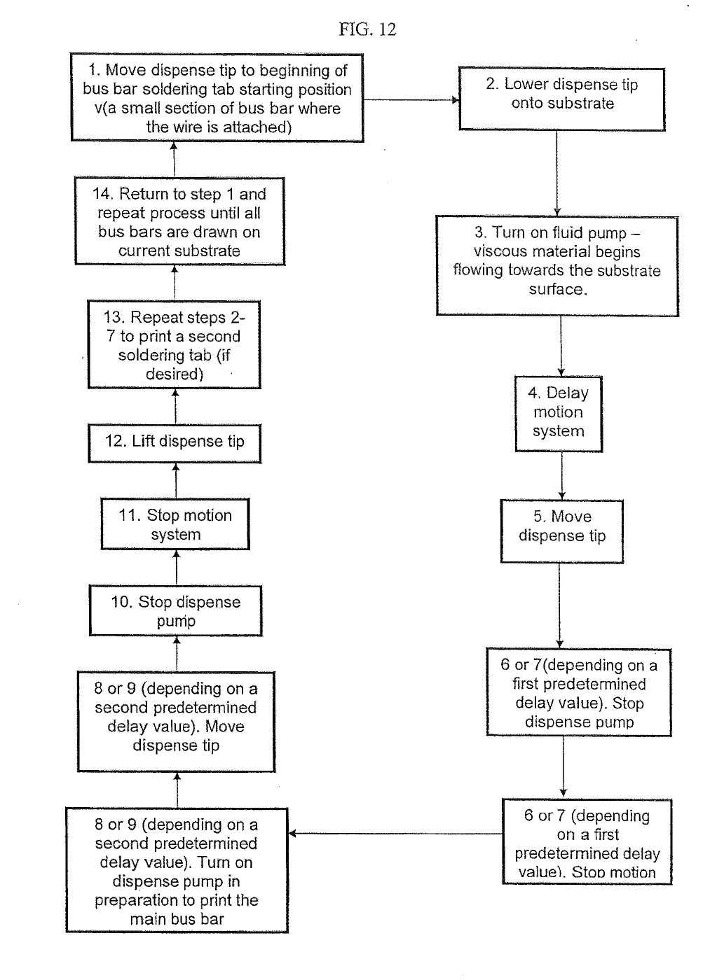

In the first stage, as exemplified in step 1 of FIG. 12, the motion system is moved to an appropriate X-Y coordinate starting position. More specifically, a dispensing tip having a stylus on its end is moved to the beginning of a bus bar soldering tab starting position. To perform this step, a controller first determines a current X-Y-Z coordinate position of the dispensing tip relative to a home position. The controller then retrieves the X-Y-Z coordinate positions of the substrate edges and the soldering tab starting positions, which were previously determined and stored by a computer in a separate process. The current position of the dispensing tip is then compared to these stored position parameters relative to the home position. Based on the comparison, the controller may then extrapolate an appropriate starting position of the dispensing tip and direct the motion system to move to this starting position. Once the dispensing tip is positioned appropriately, a signal is sent to the controller.

Then, as shown in step 2, the motion system moves to the appropriate Z-coordinate starting position and lowers the dispensing tip onto the substrate. Specifically, a controller directs the actuator to lower the dispensing tip to a point in which the stylus is contacting the surface of the substrate based on the thickness of the substrate. The forces acting between the stylus and the substrate should be sufficient to ensure the dispensing tip remains in full and constant contact with the substrate during printing but should not exceed an amount that may damage the substrate or the stylus. Preferably, these forces are approximately about 1 to 2 lbs. If, however, the stylus does not contact the substrate prior to reaching a predetermined distance above the supporting fixture surface which varies based on substrate thickness, the actuator sends a signal to the controller which then directs the actuator to stop and return to its home position. It is believed that this may prevent damage to the dispensing tip and dispensing of the viscous material on the supporting fixture rather than the intended substrate.

When the actuator determines that the stylus has contacted the substrate, the controller verifies this contact and then directs the actuator to switch to an alternative mode referred to herein as a “force mode”. While in the force mode, the actuator mechanically pushes the dispensing tip against the substrate with a predetermined amount of force ranging from about 1 to about 2 lbs.

As demonstrated in step 3, a fluid pump is then activated. For example, the controller may instruct the pump to activate and begin pumping viscous material at a predetermined rate, ultimately dispensing it onto a substrate in coordination with the predetermined movements made by the motion system.

According to step 4, movement of the motion system begins after a predetermined and variable delay time is reached. In some embodiments, the delay time ranges between about 50 msec and about 100 msec.

In some embodiments, movement of the motion system is preprogrammed with a negative delay time such that the pump is activated prior to movement of the motion system. In other embodiments, movement of the motion system is programmed with a positive delay time such that the pump is activated after movement of the motion system, such that a greater amount of material could be applied at the start of the bead of applied material than elsewhere along the bead. It is to be understood that in other embodiments, a positive or negative delay may have the reverse effect of these embodiments.

In step 5, the dispensing tip moves across the substrate while dispensing the viscous material to print at least a portion of the soldering tab and thus create a conductive terminal. To perform this step, the controller commands a set of axis controllers to move the motion system to predetermined destination coordinates corresponding to the X-Y coordinates of the position of at least a portion of the first tab nearest the dispensing tip and then to dispense viscous material in a predetermined manner over the predetermined coordinates of at least a portion of the tab. In this manner, it is believed that the viscous material is uniformly dispensed from the dispensing tip while the tip is in motion in at least one coordinate direction.

The dispensing tip may have a flat face and an apex on an end of the stylus that contacts the substrate that are spaced apart at a predetermined distance during the movement of the motion system. This predetermined distance may be fixed or variable at different positions of the motion system. In this manner, the distance between the flat face and the apex determines the thickness of the viscous material. This thickness remains the same when the predetermined distance between the apex and the flat face remains constant.

During a pump stopping process identified as step 6, the computer monitors the X-Y coordinates of the motion system during the tab drawing process. When these coordinates place the dispensing tip at a predetermined position prior to the end of the tab stop position, the computer sends a stop command to the pump. Upon receiving this command, the pump decelerates to a predetermined speed at a predetermined deceleration rate in order to prevent excess material from being dispensed.

As illustrated in step 7, the computer also sends a quit command to the axis controllers of the motion system to reach a predetermined position at the end of the tab stop. Upon receiving this command, the motion system decelerates at a predetermined deceleration to prevent excess material from being displaced beyond a predefined region.

Steps 6 and 7 may be performed in any order depending on whether the first delay value is positive or negative.

A bus bar is printed during a second stage. At the start of the second stage, the pump and the motion system are again activated, as shown in steps 8 and 9 of FIG. 12. Once activated, the pump and the motion system then operate at the predetermined acceleration and speed settings as described herein. The controller monitors the motion system during the dispensing or printing process. When the dispensing tip gets close to the position where the bus bar will terminate, it commands the pump to stop or decelerate, according to predetermined parameters, as illustrated at step 10. When the dispensing tip reaches the coordinates where the bus bar ends, the computer sends a command to the motion system controllers to stop, as illustrated at step 11. Finally, the controller sends a command to move the dispensing tip in an upward direction, as illustrated at step 12, and, optionally, to return the motion system to a home position.

In a step 13, the first stage may then be repeated after printing the bus bar, if desired. In this manner, steps 2 through 7 may be repeated to apply viscous material to the substrate to print a second soldering tab.

As shown by step 14, each of the steps 1-12 may be repeated on further tab stops and bus bars drawn on the same substrate.

In some embodiments, the bus bar is printed such that it bridges preprinted soldering tabs placed on the substrate prior to the sequence for printing a bus bar. In some instances, the soldering tab may be printed by a separate system such as that described herein. The soldering tab may be made out of a suitably conductive material that may be different than the material used for the bus bar. In some embodiments, the bus bar printing may begin on the preprinted soldering tab such that the bus bar directly contacts the preprinted soldering tab.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A dispensing tip capable of fluid communication with a pump for use in dispensing a viscous material comprising:
an outer housing;
an inner housing engaged with and located within said outer housing;
a contact element engaged with and located within said inner housing, said contact element extending outside said outer and inner housings; and
at least one outlet hole located within a space defined by said outer housing, said inner housing, and said contact element.

2. The dispensing tip of claim 1, wherein said contact element includes an apex, said apex being substantially a point surface capable of contacting a suitable surface for receiving the viscous material.

3. The dispensing tip of claim 1, wherein said at least one outlet hole includes an inner portion defined by the outer housing and the inner housing and an outer portion defined by the outer housing and the contact element.

4. The dispensing tip of claim 1, wherein said dispensing tip has at least two outlet holes spaced apart equally along a circumference within said space.

5. The dispensing tip of claim 1, wherein said contact element retains substantially the same shape at an applied force of less than 3 lbs.

6. The dispensing tip of claim 1, wherein said contact element is made of a material selected from the group consisting essentially of stainless steel, sapphire, and polycrystalline diamond.

7. The dispensing tip of claim 1, wherein said space has a volume between about 0.2 cubic centimeters and about 0.25 cubic centimeters.

8. The dispensing tip of claim 1, wherein said contact element has a cylindrical central portion.

9. The dispensing tip of claim 1, wherein said contact element is spherical.

10. The dispensing tip of claim 1, wherein said outer housing is threadedly engaged with said inner housing.

11. The dispensing tip of claim 2, said outer housing having a face, wherein a distance between said face and said apex remains substantially constant.

12. The dispensing tip of claim 10, wherein said engagement of said inner housing and said contact element is an interference fit.

13. A computer-controlled system for dispensing a viscous material within a region having X-, Y-, and Z-positions comprising:
a motion system capable of (i) receiving at least one signal and (ii) moving to predetermined positions in response to said at least one signal received;
a variable pressure supply device capable of (i) receiving at least one signal and (ii) delivering a fluid in response to said at least one signal received; and
a dispensing tip having an end that defines its X-, Y-, and Z-positions, the dispensing tip being (i) coupled to said motion system such that it moves with said motion system to predetermined X-, Y-, and Z-positions and (ii) in fluid communication with the variable pressure supply device.

14. The computer-controlled system for dispensing viscous material of claim 13, wherein said variable pressure supply device is a pump capable of (i) receiving an input signal from said motion system and (ii) adjusting the flow rate to a rate proportional to said input signal.

15. The computer-controlled system of claim 13, further comprising:
a user interface capable of receiving and transmitting data; and
a controller capable of (i) receiving any of said data, (ii) converting any of said data into said signals, and (iii) transmitting any of said signals.

16. The computer-controlled system of claim 15, wherein
said data includes predetermined pump flow rates, predetermined displacement parameters, predetermined speed parameters, and predetermined acceleration parameters, and
said signals include flow rate signals, displacement signals, speed signals, and acceleration signals.

17. The computer-controlled system for dispensing a viscous material of claim 13 further adapted for dispensing the viscous material from said dispensing tip onto a substrate, wherein said end of said dispensing tip is a center stylus capable of locating and maintaining contact with the substrate at predetermined positions.

18. The computer-controlled system of claim 13, wherein the dispensing tip further comprises at least one outlet hole capable of dispensing viscous material.

19. A method for uniformly dispensing a viscous material within a dispensing region comprising the steps of:
moving a dispensing tip in a controlled direction at a controlled speed and acceleration within the dispensing region; and
delivering said viscous material at a controlled flow rate in coordination with the step of moving said dispensing tip to deliver a predetermined amount of said viscous material to predetermined positions within the dispensing region.

20. The method of claim 19, further comprising the steps of:
receiving a stop command at a predetermined tab stop position;
decelerating said dispensing tip to a lower controlled speed at said predetermined stop position; and
reducing said flow rate to a lower controlled flow rate for delivering said viscous material after reaching said predetermined stop position.

21. The method of claim 19, wherein the dispensing tip comprises an outer housing having a face, wherein a distance between said face and said dispensing region remains substantially fixed to form a uniform thickness of viscous material.

22. The method of claim 19, wherein said dispensing tip is in fluid communication with a variable pressure supply device, said variable pressure supply device being capable of producing variable flow rates, and wherein said dispensing tip is coupled to a motion system, said motion system being movable in three dimensions, further comprising the steps of:
receiving a signal at an electrical interface of the variable pressure supply device from said motion system; and
adjusting the flow rate of said variable pressure supply device to supply viscous material to said dispensing tip such that said dispensing tip dispenses a predetermined uniform amount of said viscous material.

23. The method of claim 19, wherein said dispensing region is substantially linear.

24. The method of claim 19, wherein the viscous material is glass frit.

25. The method of claim 19, wherein the dispensing region is a projection of a soldering tab.

26. The method of claim 19, wherein the dispensing region is a projection of a bus bar.

27. The method of claim 19, wherein the dispensing region includes at least a portion of a substrate.

28. The method of claim 19, wherein the dispensing region includes a soldering tab portion in which the viscous material will be dispensed, said method further comprising the steps of:
receiving a first delay value prior to dispensing the viscous material in said soldering tab portion, wherein a delay value corresponds to a time between movement of said dispensing tip and activation of a variable pressure supply device, the variable pressure supply device being in fluid communication with said dispensing tip.

29. The method of claim 28, wherein the dispensing region further includes a bus bar portion in which the viscous material will be dispensed, said method further comprising the steps of:
receiving a second delay value, prior to dispensing the viscous material in said bus bar portion;
reactivating the variable pressure supply device;
further delivering said viscous material at a controlled flow rate in coordination with the step of moving said dispensing tip to deliver a predetermined amount of said viscous material at predetermined coordinates onto said substrate within the dispensing region;
further moving said dispensing tip in a controlled direction at a controlled speed and acceleration along said substrate within the entire dispensing region;
decelerating said dispensing tip to a lower controlled speed immediately after the receiving of a stop command at a predetermined tab stop position; and
reducing the flow rate to a lower controlled flow rate for delivering the fluid after reaching a predetermined stop position;
stopping the delivering of the fluid after the reducing of the flow rate;
stopping the movement of dispensing tip at a predetermined location; and
returning the dispensing tip to the home position.

30. The method of claim 29, wherein the dispensing region further includes a second soldering tab portion in which the viscous material will be dispensed for use in producing a full bus bar with soldering tabs at each end, further comprising the steps of:
receiving a third delay value, prior to dispensing the viscous material in said second soldering tab portion;
further moving said dispensing tip in a controlled direction at a controlled speed and acceleration along said substrate within the entire dispensing region;
reactivating a variable pressure supply device;
further delivering said viscous material at a controlled flow rate in coordination with the step of moving said dispensing tip to deliver a predetermined amount of said viscous material at predetermined coordinates onto said substrate within the dispensing region;
decelerating said dispensing tip to a lower controlled speed immediately after the receiving of a stop command at a predetermined tab stop position; and
reducing the flow rate to a lower controlled flow rate for delivering the fluid after reaching a predetermined stop position;
stopping the delivering of the fluid after the reducing of the flow rate; and
stopping the movement of dispensing tip at a predetermined location.
